(19) United States
(12) Patent Application Publication
(10) Pub. No.: US 2026/0016532 A1
(43) Pub. Date: Jan. 15, 2026

(54) INSPECTION APPARATUS

(71) Applicant: KABUSHIKI KAISHA NIHON MICRONICS, TOKYO (JP)

(72) Inventors: TOMOKAZU SAITO, TOKYO (JP); KATSUO YASUTA, TOKYO (JP); TAKESHI SAITO, TOKYO (JP)

(73) Assignee: KABUSHIKI KAISHA NIHON MICRONICS, TOKYO (JP)

(21) Appl. No.: 19/262,745

(22) Filed: Jul. 8, 2025

(30) Foreign Application Priority Data
Jul. 12, 2024 (JP) 2024-112778

(51) Int. Cl. G01R 31/28

(52) U.S. Cl. CPC G01R 31/2877; G01R 31/2889; G01R 31/2891

(57) ABSTRACT

An inspection apparatus that brings an electrical contactor into contact with an electrode terminal of a device under test on a wafer, electrically connects a tester and the device under test via the electrical contactor, and performs testing of the device under test. The inspection apparatus includes a wafer support portion for supporting the wafer, an infrared-light receiving unit for receiving infrared radiation emitted from the wafer with at least the wafer as a measurement target, and a temperature measurement control unit for controlling temperature measurement of the measurement target based on an infrared radiation amount of the infrared radiation received by the infrared-light receiving unit. The temperature measurement control unit includes a temperature correction unit that corrects the measurement temperature based on the infrared radiation amount from the wafer.

### CROSS-REFERENCE TO RELATED APPLICATIONS

The present application claims priority under 35 U.S.C. § 119 to Japanese Patent Application No. 2024-112778, filed on Jul. 12, 2024. The contents of this application are incorporated herein by reference in their entirety.

### TECHNICAL FIELD

The present disclosure relates to an inspection apparatus, for example, to one that can be applied to a semiconductor inspection apparatus (hereinafter also referred to simply as “inspection apparatus”) for testing electrical characteristics of a semiconductor integrated circuit (hereinafter also referred to as “semiconductor device”) formed on a semiconductor wafer (hereinafter also referred to simply as “wafer”).

### BACKGROUND ART

In the manufacturing process of semiconductor devices formed on a wafer, it is necessary to test whether electrical characteristics of the semiconductor devices satisfy predetermined values, and a semiconductor inspection apparatus equipped with a probe card is used for this testing.

For example, a probe card having a plurality of probes is connected to a test head, bringing the terminals of the semiconductor devices on the wafer into contact with the probes. Then, through the probes, the tester applies test signals to each semiconductor device on the wafer, and acquires the response signals from each semiconductor device to test electrical characteristics of each semiconductor device.

In recent years, it has become necessary to test whether the electrical characteristics of the semiconductor devices satisfy predetermined values even under predetermined temperature environments, and therefore it is necessary to accurately and precisely measure the surface temperature of the wafer (semiconductor device) under test. Conventionally, a temperature measuring device described in Patent Document 1 has been used to measure a surface temperature of wafers, which measures an amount of infrared radiation radiated from the wafers using an infrared sensor (see Patent Literature 1).

In this case, it is necessary to calibrate the temperature measuring device using the emissivity of a black body. A conventional calibration method involves, for example, removing the temperature measuring device from the prober and calibrating it using the radiation temperature of a black body furnace or the like as a reference. Alternatively, a wafer-shaped black body is placed on the chuck of the prober, and changes in the measured infrared radiation amount are actively monitored to confirm that the values remain within a certain range. When the measured values deviate from the defined range, the accuracy is reconfirmed using the wafer-shaped black body, and recalibration is performed if necessary. In this manner, the temperature of the wafer is measured in a non-contact manner using the infrared sensor.

### CITATION LIST

### Patent Literature

Patent Literature 1: Japanese Unexamined Patent Application Publication No. 2001-56253

### SUMMARY OF INVENTION

### Technical Problem

However, when measuring the surface temperature of a wafer (semiconductor device) during testing using a non-contact temperature sensor, the semiconductor device generates heat when an operating current is applied, and heat is further transferred to the electrical signal probe that contacts the terminal of the semiconductor device, so that temperature of the semiconductor device change and it is difficult for the temperature to stabilize.

As a result, a significant temperature difference occurs between the applied surface temperature of the wafer (semiconductor device) and the actual temperature of the semiconductor device using conventional techniques.

While the method of measuring temperature using an infrared sensor is effective for non-contact, responsive and high-speed temperature measurement of the wafer surface, the following types of correction are necessary to achieve higher accuracy, but such correction methods have not yet been established.

Measurement data from the infrared sensor is transmitted to the temperature measurement system through an optical path formed of components such as optical fibers, lens barrels, and lenses, but the transmittance deteriorates due to the fitting condition or degradation of the optical path components.

In addition, when the temperature of the optical path itself rises, infrared radiation is emitted from the optical path itself, potentially affecting the measurement.

Furthermore, the amount of infrared radiation emitted from the wafer, which is the object to be measured, changes depending on conditions such as the surface color or roughness of the wafer.

Moreover, the amount of received light is changed due to changes in the incident angle caused by variations in the distance between the light-receiving surface (e.g., the fiber tip) and the workpiece.

To solve the above-mentioned issues, the present disclosure aims to provide an inspection apparatus that can correct factors that may cause errors when measuring the surface temperature of a wafer having multiple test subjects in a non-contact manner using an infrared sensor, enabling measurement with good precision.

### Solution to Problem

To solve the above issues, the present disclosure provides an inspection apparatus which brings an electrical contactor into contact with an electrode terminal of a device under test formed on a wafer, electrically connects a tester and the device under test via the electrical contactor, and tests the device under test, the inspection apparatus comprising: a wafer support portion configured to support the wafer; an infrared-light receiving unit configured to receive infrared radiation emitted from the wafer, at least with the wafer as a measurement target; and a temperature measurement control unit configured to control temperature measurement of the measurement target based on an infrared radiation amount of the infrared radiation received by the infrared-light receiving unit, wherein the temperature measurement control unit includes a temperature correction unit configured to correct the measurement temperature based on the infrared radiation amount of the wafer.

### Advantageous Effects of Invention

According to the present disclosure, when measuring the surface temperature of a wafer having multiple test subjects in a non-contact manner using an infrared sensor, factors that may cause measurement errors can be corrected, and the temperature can be measured with good precision.

### BRIEF DESCRIPTION OF DRAWINGS

FIG. 1 is an overall configuration diagram illustrating the overall configuration of an inspection apparatus according to a first embodiment.

FIG. 2 is a top view showing the configuration of a chuck according to the first embodiment.

FIG. 3 is a flowchart illustrating the operation of calibration processing of a temperature measuring device in the inspection apparatus according to the first embodiment (Part 1).

FIG. 4 is an explanatory view illustrating the positional movement of a black body according to the first embodiment.

FIG. 5 is a flowchart illustrating the operation of calibration processing of the temperature measuring device in the inspection apparatus according to the first embodiment (Part 2).

FIG. 6 is an explanatory view illustrating distance measurement by a distance sensor according to the first embodiment.

FIG. 7 is a diagram showing the relationship between the distance between a wafer and an infrared-light receiving unit and correction temperature according to the first embodiment.

FIG. 8 is a diagram showing the relationship between ambient temperature and correction temperature according to the first embodiment.

FIG. 9 is an explanatory view illustrating fiber temperature correction processing according to the first embodiment.

FIG. 10 is a diagram showing the relationship between the temperature of an optical fiber and the correction temperature corresponding to the increase in infrared radiation of the optical fiber according to the first embodiment.

FIG. 11 is an explanatory view illustrating ferrule temperature correction processing according to the first embodiment.

FIG. 12 is a diagram showing the relationship between the temperature of a ferrule and the correction temperature corresponding to the increase in infrared radiation of the ferrule according to the first embodiment.

FIG. 13 is an explanatory view illustrating the arrangement of temperature sensors provided on the optical fiber and the ferrule according to the first embodiment.

FIG. 14 is a diagram showing the wafer surface temperature before and after correction by the temperature measuring device according to the first embodiment.

### DESCRIPTION OF EMBODIMENTS

### (A) First Embodiment

Hereinafter, a first embodiment of an inspection apparatus according to the present disclosure will be described in detail with reference to the drawings.

In the drawings relating to the embodiment, the same reference numerals are assigned to equivalent parts. However, the drawings are schematic, and the thickness ratios of the respective components may differ from those in actual products. Also, dimensional relationships or ratios between drawings may differ. This embodiment illustrates devices and methods for embodying the technical concept of the invention, and does not limit the materials, shapes, structures, or arrangements of the components to those described in the embodiment.

### (A-1) Configuration of First Embodiment

### (A-1-1) Overall Configuration

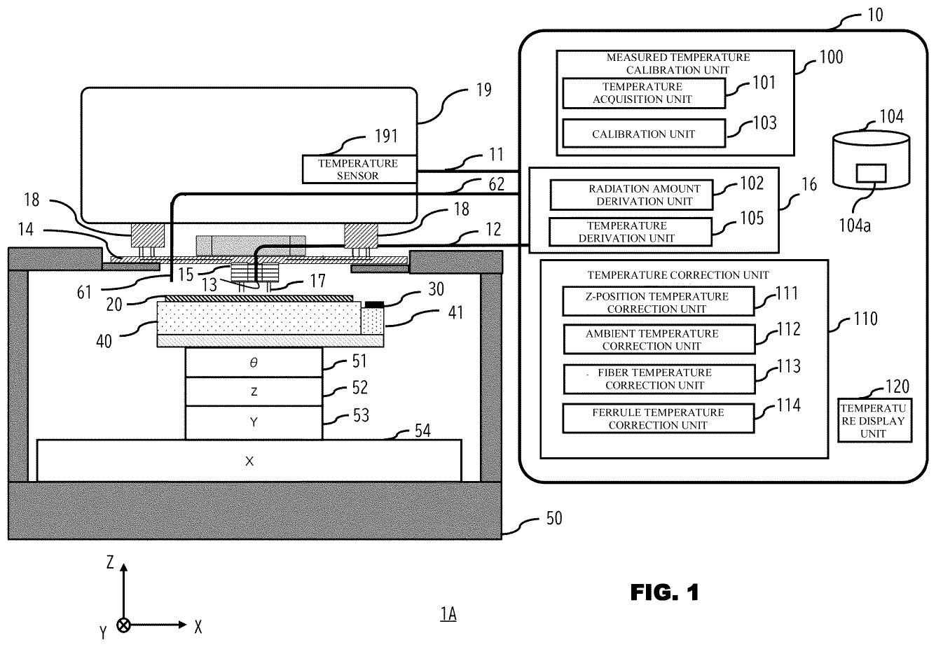

FIG. 1 is an overall configuration diagram showing the overall structure of the inspection apparatus according to the first embodiment.

In FIG. 1, the inspection apparatus 1 according to the first embodiment includes a temperature measuring device 10, a prober 50, and a test head 19.

Also, in FIG. 1, the prober 50 includes a chuck 40 having a temperature adjustment function that supports a wafer 20 and adjusts the temperature of the wafer 20 to a high or low temperature, and a θ-axis stage 51, a Z-axis stage 52, a Y-axis stage 53, and an X-axis stage 54, which serve as drive mechanisms for movement.

The inspection apparatus 1 tests the electrical characteristics of each semiconductor device (hereinafter also referred to as “device under test”) formed on the wafer 20. A probe card 14 is electrically connected to a second surface (e.g., bottom surface) of the test head 19 via an electrical connection unit 18. During testing, each probe 17 of the probe card 14 is brought into electrical contact with the electrode terminals of the semiconductor device. Then, the inspection apparatus 1 provides electrical signals from the tester to each semiconductor device on the wafer 20 via the probes, and acquires the signals returned from each semiconductor device to send them back to the tester. In this way, the tester performs characteristic testing of the semiconductor devices.

The test head 19 is connected to the probe card 14 via the electrical connection unit 18 on the second surface (e.g., bottom surface). The test head 19 is connected to a main body of a tester (not shown) and electrical signals are exchanged between the main body and the probe card 14. This enables testing of the electrical characteristics of the semiconductor devices on the wafer 20.

The electrical connection unit 18 is a mounting unit for mounting the probe card 14 onto the test head 19 and electrically connecting the test head 19 and the probe card 14.

The probe card 14 brings the probe 17 into contact with the electrode terminals of the semiconductor device formed on the wafer 20, applies electrical signals to the semiconductor device via the probe 17, and receives response signals from the semiconductor device via the probe 17. The probe card 14 is an example of an electrical connection device for electrically connecting the tester main body and the semiconductor devices on the wafer 20. The probe card 14 installs a probe assembly 15 having a plurality of probes 17 on the second surface (e.g., bottom surface) side.

The probe assembly 15 is an assembly including the plurality of probes 17 and is provided on the second surface side of the probe card 14.

Each probe 17 is an electrical contactor that makes electrical contact with an electrode terminal of the semiconductor device. The type of the probe 17 is not particularly limited, and, for example, cantilever-type probes or vertical-type probes may be used.

In this embodiment, an example is described in which the probe 17 is an electrical contactor that electrically contacts an electrode terminal of a semiconductor device. However, if the semiconductor device is an optical semiconductor, the probe 17 may include not only an electrical contactor but also an optical probe (e.g., optical fiber) for transmitting and receiving optical signals with the optical input/output portion of the optical semiconductor.

The chuck 40 fixes the wafer 20 on its upper surface (also referred to as “chuck top” or “chuck stage”) and moves in the XYZ θ-axis directions. Also, the chuck 40 has a temperature adjustment function for adjusting the temperature of the wafer 20 fixed to its upper surface. Moreover, the chuck 40 has installed one or more black bodies 30 on the upper surface of the chuck 40. The method of placing the black bodies 30 will be described later.

The θ-axis stage 51, Z-axis stage 52, Y-axis stage 53, and X-axis stage 54 are drive mechanisms that move the chuck 40.

The temperature measuring device 10 is connected to an optical fiber 12 that is connected to an infrared-light receiving unit 13. The infrared-light receiving unit 13 receives infrared radiation emitted from the measurement target object (hereinafter also referred to simply as “measurement target”), and the temperature measuring device 10 acquires the infrared radiation emitted from the measurement target via the optical fiber 12. The temperature measuring device 10 converts the amount of infrared radiation input from the infrared-light receiving unit 13 into temperature to measure the surface temperature of the measurement target. This allows for non-contact measurement of the surface temperature of the measurement target.

Further, the temperature measuring device 10, periodically or as necessary, measures the surface temperature of the black body 30 placed on the first surface (e.g., upper surface) of the chuck 40 and performs correction of the measurement temperature of the temperature measuring device 10.

Furthermore, the temperature measuring device 10 is connected to a distance sensor 61 via an optical fiber 62. The temperature measuring device 10 obtains distance information from the distance sensor 61 and derives the distance between the infrared sensor 16 and the wafer 20.

### (A-1-2) Detailed Configuration of Temperature Measuring Device 10

In FIG. 1, the temperature measuring device 10 broadly includes: an infrared sensor 16, a measured temperature calibration unit 100, a temperature correction unit 110, a storage unit 104, and a temperature display unit 120.

The temperature measuring device 10 is a device that includes components such as a CPU, ROM, RAM, EEPROM, and input/output interface unit. The temperature measuring device 10 may perform temperature measurement processing in hardware. Alternatively, an application software (e.g., a temperature measurement program) may be installed in the ROM, and the CPU may execute the software to realize the functions of the temperature measuring device 10. In any case, the functions of the temperature measuring device 10 can be represented by the functional blocks illustrated in FIG. 1.

### [Infrared Sensor 16]

The infrared sensor 16 converts the amount of infrared radiation input from the infrared-light receiving unit 13 into temperature to measure the surface temperature of the measurement target. The infrared sensor 16 is a non-contact temperature conversion unit (non-contact thermometer) that converts the amount of infrared radiation into temperature. The infrared sensor 16 includes a radiation amount derivation unit 102 and a temperature derivation unit 105.

The radiation amount derivation unit 102 collects infrared radiation of the measurement target received by the infrared-light receiving unit 13 via the optical fiber 12 and derives the amount of infrared radiation emitted from the measurement target.

The temperature derivation unit 105 derives temperature based on the infrared radiation amount of the measurement target derived by the radiation amount derivation unit 102. Here, existing methods can be applied to derive the temperature, such as converting the infrared radiation amount into temperature based on the relationship between the infrared radiation amount and the temperature (e.g., Planck's law of radiation). This allows the temperature to be determined based on the infrared radiation amount.

### [Measured Temperature Calibration Unit 100]

The measured temperature calibration unit 100 calibrates the temperature value of the wafer 20 (semiconductor device) measured by the temperature measuring device 10 periodically or during testing. By calibrating the temperature value of the infrared sensor 16 periodically or during testing, temperature can be measured with good precision. Furthermore, as described later, because the temperature of the wafer 20 (semiconductor device) can be calibrated using a non-contact sensor such as the infrared sensor 16, calibration can be performed with good responsiveness and high speed in a non-contact manner.

The measured temperature calibration unit 100 includes a temperature acquisition unit 101 and a calibration unit 103.

The storage unit 104 stores a reference table 104a showing the relationship between the temperature of the black body 30, which will be described later, and the amount of infrared radiation (hereinafter also referred to simply as “radiation”). The storage unit 104 also stores processing programs, data necessary for processing, and the like.

The temperature acquisition unit 101 acquires the temperature of the measurement target from a temperature sensor 191.

The calibration unit 103 creates a correction table based on the relationship between the radiation and the temperature of the black body 30, and using that correction table, performs correction of measurement values due to time-dependent changes of the infrared sensor 16, applies correction values for the temperature measuring device 10, and performs abnormality detection.

### [Temperature Correction Unit 110]

The temperature correction unit 110 corrects temperature errors due to factors (correction elements) that may cause deviations when measuring the surface temperature of the wafer 20 (semiconductor device) using the infrared sensor 16.

The temperature correction unit 110 includes a Z-position temperature correction unit 111, an ambient temperature correction unit 112, a fiber temperature correction unit 113, and a ferrule temperature correction unit 114.

The temperature correction unit 110 may combine any of the processing units—Z-position temperature correction unit 111, ambient temperature correction unit 112, fiber temperature correction unit 113, and ferrule temperature correction unit 114—but here, a case where all of them are included is exemplified.

The Z-position temperature correction unit 111 corrects temperature in response to the distance (i.e., length in the Z-axis direction; height) between the infrared-light receiving unit 13, located at the tip of the optical fiber 12, and the measurement target (e.g., the wafer 20).

For example, if the distance between the infrared-light receiving unit 13 and the wafer 20 is short, more infrared radiation is incident on the infrared-light receiving unit 13, whereas if the distance is long, the amount of incident infrared radiation is expected to be reduced. Therefore, the temperature is corrected using a correction value corresponding to the actual distance, based on the relationship between the distance between the infrared-light receiving unit 13 and the wafer 20 and the correction value.

The ambient temperature correction unit 112 corrects the temperature in response to changes in the ambient temperature (e.g., room temperature) in which the infrared sensor 16 is placed.

For example, the infrared sensor 16 uses a preamplifier (amplifier) to amplify the intensity of the infrared radiation emitted by the measurement target. The value of the measured temperature may vary due to changes in the ambient temperature (room temperature) of the environment where the preamplifier of the infrared sensor 16 is placed. Therefore, the ambient temperature correction is performed in response to the changes in room temperature, by referencing the relationship between the ambient temperature of the environment where the preamplifier is placed and the corresponding temperature correction value.

The fiber temperature correction unit 113 corrects the temperature according to temperature changes of the optical fiber itself, which are caused by heat transferred from the chuck 40 that has a temperature control function.

For example, the optical fiber connected to the infrared sensor 16 becomes hotter due to heat transferred from the chuck 40. In addition, the probe assembly 15 also receives heat transferred from the chuck 40, and the probes 17 themselves become hot, thereby transferring heat through the probes 17, so the probe assembly 15 itself becomes hot, resulting in temperature changes in the optical fiber. Therefore, the fiber temperature correction unit 113 corrects the surface temperature of the wafer 20 in response to the temperature change of the optical fiber itself.

In this case, in order to measure the temperature of the optical fiber itself, for example, a temperature sensor 191 such as a thermocouple is attached to the target optical fiber, so that the temperature sensor 191 measures the temperature of the optical fiber itself and provides temperature information to the temperature measuring device 10. The fiber temperature correction unit 113 uses the temperature information sensed by the temperature sensor 191 to correct the surface temperature value of the wafer 20.

The ferrule temperature correction unit 114 corrects the temperature in response to changes in the temperature of a ferrule used when inserting the optical fiber 12 into a through-hole provided in the probe card 14.

For example, in order to facilitate replacement of the optical fiber 12, a ferrule in the form of a flanged tubular member is inserted into the through-hole of the probe card 14, and the optical fiber 12 is then inserted into the tube of the ferrule. During testing, the temperature of the ferrule itself also changes, so the ferrule temperature correction unit 114 corrects the surface temperature of the wafer 20 in response to the temperature change of the ferrule.

Here, a case in which all four correction methods are performed is described, but any combination of the four correction methods may be used.

### [Temperature Display Unit 120]

The temperature display unit 120 displays the temperature derived by the infrared sensor 16, the calibrated temperature from the measured temperature calibration unit 100, and the corrected temperature from the temperature correction unit 110. For example, a display unit such as a liquid crystal display (LCD) can be used as the temperature display unit 120.

### (A-1-3) Detailed Configuration of Chuck 40

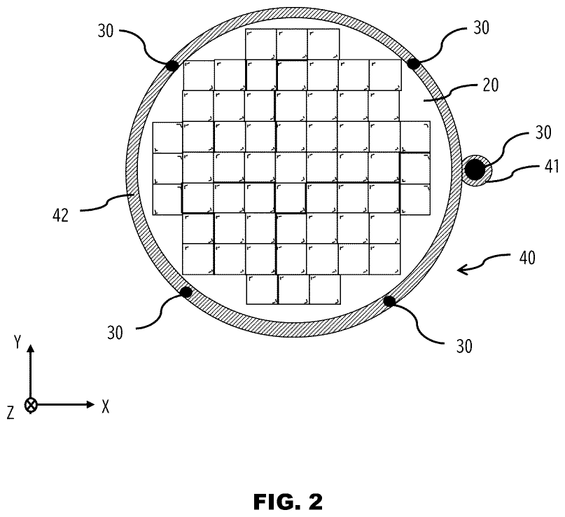

FIG. 2 is a top view showing the configuration of the chuck 40 according to the first embodiment.

As shown in FIG. 2, the wafer mounting surface of the chuck 40 (i.e., the shape of the chuck top) is approximately circular, and the size of the chuck 40 is slightly larger than the size of the wafer 20.

On a peripheral portion 42 of the wafer mounting surface of the chuck 40, the black bodies 30 whose relationship between temperature and infrared radiation amount is known in advance are disposed.

In the example of FIG. 2, a total of five black bodies 30 are provided: four black bodies 30 on the peripheral portion 42 of the wafer mounting surface of the chuck 40, and one black body 30 on a black body mounting portion 41 formed in the peripheral portion 42. The four black bodies 30 are disposed at equal intervals on the peripheral portion 42 of the chuck 40.

The number of black bodies 30 is not limited to this example. A single black body 30 may be placed on the chuck 40, or two or more black bodies 30 may be disposed. The black bodies 30 are used as a reference for infrared radiation. In addition, as long as the black body 30 can be moved to the position of the infrared-light receiving unit 13 when calibrating the temperature measuring device 10, the arrangement is not particularly limited.

The black body 30 is a thermal radiator whose relationship between temperature and infrared radiation amount is known in advance. For example, the black body 30 may be a black body seal in the form of a sticker, or a surface coated with black body paint, among other configurations.

When there is an abnormality in the measurement accuracy of the temperature measuring device 10 or in the measurement result of the infrared sensor 16, the black body 30 is used to convert the infrared radiation amount into temperature and generate a correction table based on the result. This correction table is then referenced to correct the output value of the temperature signal from the temperature measuring device 10.

In other words, during testing or at regular intervals, the infrared radiation amount from the black body 30 is measured, and the temperature is derived from the infrared radiation amount. By comparing the derived temperature with the correction table, the output value of the temperature signal from the temperature measuring device 10 can be calibrated.

Since the black body 30 is disposed on the wafer mounting surface of the chuck 40, even during testing, the black body 30 can be moved to the position of the infrared-light receiving unit 13 for measurement, allowing calibration of the temperature signal output value from the temperature measuring device 10 without replacing the wafer 20.

Note that the black body 30 does not need to be a perfect black body; anything that can be regarded as a black body can be used. For example, instead of disposing a separate black body 30, a portion or the entire upper surface (chuck top) of the chuck 40 may be formed with a black body color.

### (A-2) Operation of First Embodiment

Next, the processing operation for measuring the temperature of the wafer 20 (semiconductor device) in the inspection apparatus 1 according to the first embodiment will be described with reference to the drawings.

### (A-2-1) Calibration Processing

First, an example of a calibration method for calibrating the measurement values by the temperature measuring device 10 during testing or at regular intervals will be described.

### (A-2-1-1) First Calibration Processing

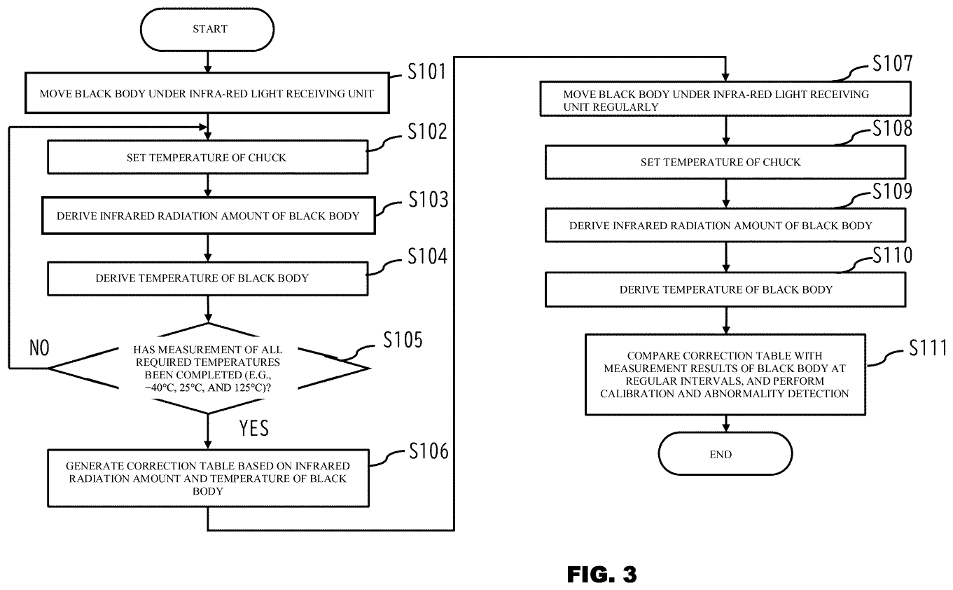

FIG. 3 is a flowchart illustrating the operation of the calibration processing of the temperature measuring device 10 in the inspection apparatus 1 according to the first embodiment (Part 1).

Here, an example of periodic calibration of an optical fiber-type non-contact thermometer as the temperature measuring device 10 is described. Note that the sequence of the calibration processing is not limited to that shown in FIG. 3.

### [Step S101]

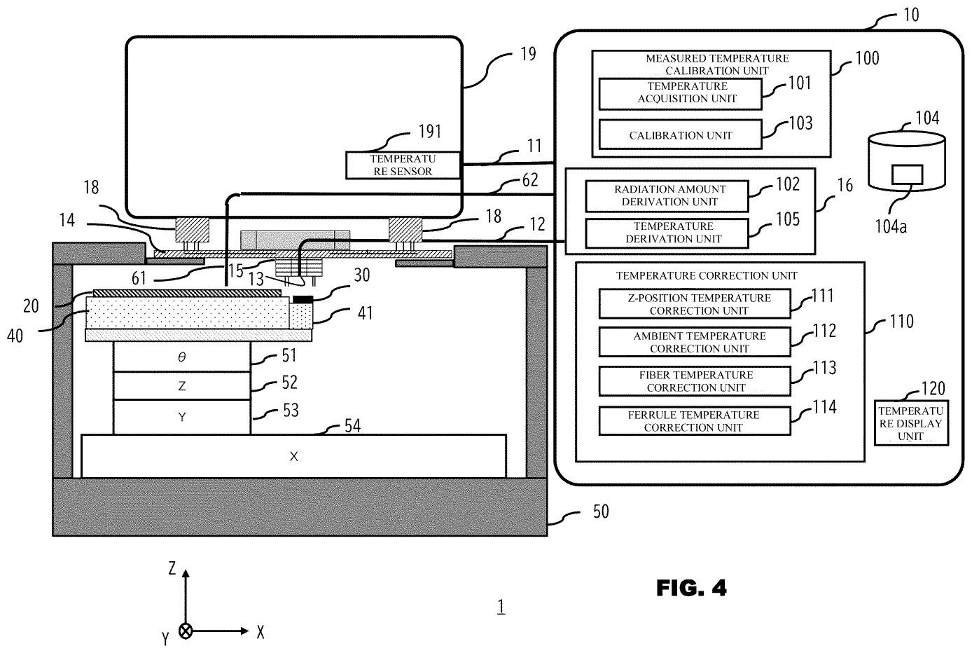

First, the movement drive mechanism, including the θ-axis stage 51, Z-axis stage 52, Y-axis stage 53, and X-axis stage 54 is driven, and as shown in FIG. 4, the black body 30 placed in the peripheral region or near the periphery of the wafer mounting surface of the chuck 40 is moved to the position of the infrared-light receiving unit 13 (Step S101).

### [Step S102]

Next, the temperature of the chuck 40 is set to the temperature required for measurement (Step S102). For example, in this embodiment, the temperatures may be set to “−40° C.,” “25° C.,” and “125° C.”

### [Step S103]

When the temperature of the chuck 40 reaches the set temperature, the black body 30 emits infrared radiation, which is received by the infrared-light receiving unit 13 and transmitted to the infrared sensor 16 via the optical fiber 12. In the temperature measuring device 10, the radiation amount derivation unit 102 derives the infrared radiation amount of the black body 30 based on the infrared signal from the infrared-light receiving unit 13 (Step S103).

### [Step S104]

In the temperature measuring device 10, the temperature derivation unit 105 derives the temperature based on the infrared radiation amount of the black body, using Planck's radiation law (Step S104).

### [Step S105]

Next, it is determined whether the measurement at all required temperatures (e.g., −40° C., 25° C., and 125° C.) has been completed (Step S105).

If the measurement has been completed (Step S105/YES), the process proceeds to Step S106. If it has not been completed (Step S105/NO), the process returns to Step S102 to change the temperature setting of the chuck 40 and continue the processing.

### [Step S106]

The calibration unit 103 generates a correction table (hereinafter also referred to as the “first correction table”) based on the infrared radiation amount and the derived temperature of the black body 30 (Step S106).

For example, if a pre-existing relationship table between the temperature of the black body 30 and the infrared radiation amount is available, the correction table is generated by comparing that pre-existing relationship table with the measurement results obtained in Steps S102 to S106.

### [Step S107]

Steps S107 to S113 are processes for periodically calibrating the infrared sensor 16 using the correction table created in Step S106.

First, at regular intervals, the movement drive mechanism moves the black body 30 on the chuck 40 to the position of the infrared-light receiving unit 13 (Step S107).

### [Step S108]

Next, the temperature sensor 191 provides the set temperature of the chuck 40 to the temperature measuring device 10 (Step S108).

### [Step S109]

The infrared-light receiving unit 13 receives the infrared radiation emitted by the black body 30 and transmits it to the temperature measuring device 10 via the infrared sensor 16. In the temperature measuring device 10, the radiation amount derivation unit 102 derives the infrared radiation amount of the black body 30 based on the infrared radiation from the infrared-light receiving unit 13 (Step S109).

### [Step S110]

In the temperature measuring device 10, the temperature derivation unit 105 derives the temperature based on the infrared radiation amount of the black body, using Planck's radiation law (Step S110).

### [Step S111]

The calibration unit 103 compares the correction table with the measurement results obtained in Steps S107 to S110, and based on the comparison result, detects and corrects time-dependent changes of the infrared sensor and changes in the infrared radiation amount of the wafer (Step S111).

For example, the comparison result is displayed on a display unit such as, for example, a liquid crystal display. This enables the operator to determine whether there is any abnormality in the measurement values of the infrared sensor 16.

### (A-2-1-2) Second Calibration Processing

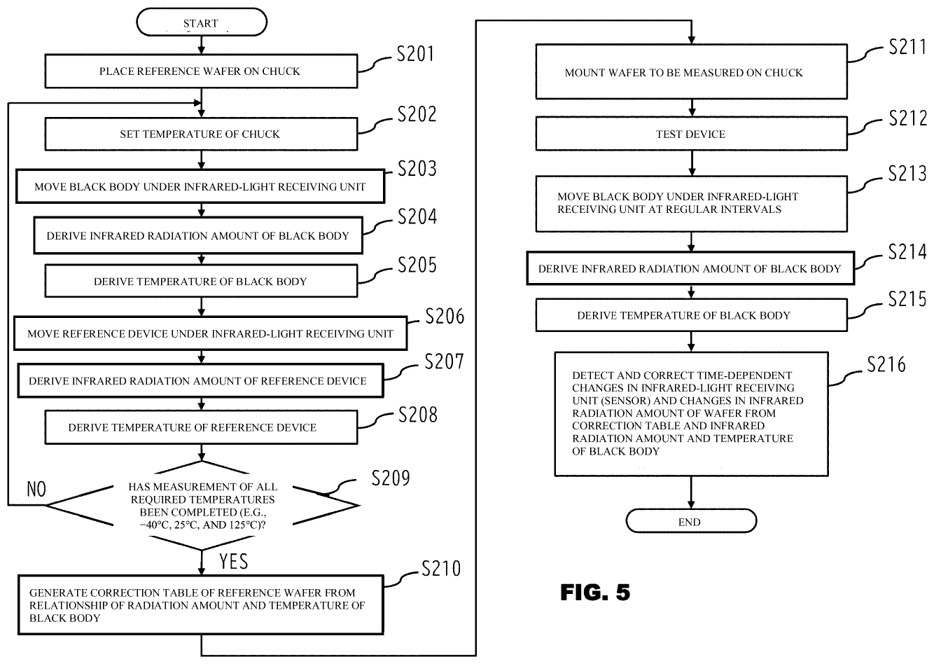

FIG. 5 is a flowchart illustrating the operation of the calibration processing of the temperature measuring device 10 in the inspection apparatus 1 according to the first embodiment (Part 2).

Here, as an example, a method for calibrating the value converted from the infrared radiation amount corresponding to the surface temperature of a semiconductor device on a wafer to the temperature during testing by the infrared sensor 16 is described. Note that the sequence of calibration processing is not limited to that shown in FIG. 5.

Note that the second calibration processing is intended to perform calibration without removing the wafer 20 to be measured from the chuck 40.

For example, when the electrical characteristics of semiconductor devices on one wafer 20 are being tested, the second calibration processing may be performed without replacing the wafer 20 and removing the temperature measuring device 10 from the prober 50. Alternatively, for example, calibration using the infrared radiation amount from the black body 30 may be performed during the interval after the testing of one wafer 20 is completed and before the next wafer 20 is mounted on the chuck 40.

### [Steps S201, S202]

First, a reference wafer is placed on the chuck 40 (Step S201), and the temperature of the chuck 40 is set to the required measurement temperature (Step S202).

For example, in this embodiment, it is illustrated that the temperatures are set to “−40° C.,” “25° C.,” and “125° C.,” but the specific temperature values are not limited to these, nor is the number of temperature settings limited to three.

### [Step S203]

The movement drive mechanism, including the θ-axis stage 51, Z-axis stage 52, Y-axis stage 53, and X-axis stage 54, is driven, and the movement drive mechanism moves the black body 30 on the chuck 40 to the position of the infrared-light receiving unit 13 (Step S203).

### [Step S204]

The infrared-light receiving unit 13 receives the infrared radiation emitted by the black body 30 and transmits it to the temperature measuring device 10. In the temperature measuring device 10, the radiation amount derivation unit 102 derives the infrared radiation amount of the black body 30 based on the infrared radiation from the infrared-light receiving unit 13 (Step S204).

### [Step S205]

In the temperature measuring device 10, the temperature derivation unit 105 derives the temperature based on the infrared radiation amount of the black body 30 using Planck's radiation law (Step S205).

### [Step S206]

Next, one of the semiconductor devices formed on the reference wafer is designated as a reference device, and the reference device is moved to the position of the infrared-light receiving unit 13 (Step S206). The reference device may be any device (semiconductor device) on the reference wafer.

### [Step S207]

The infrared-light receiving unit 13 receives the infrared radiation emitted by the reference device and transmits it to the temperature measuring device 10. In the temperature measuring device 10, the radiation amount derivation unit 102 derives the infrared radiation amount of the reference device based on the infrared radiation from the infrared-light receiving unit 13 (Step S207).

### [Step S208]

In the temperature measuring device 10, the temperature derivation unit 105 derives the temperature based on the infrared radiation amount of the reference device using Planck's radiation law (Step S208).

### [Step S209]

Next, it is determined whether measurements at all required temperatures (e.g., −40° C., 25° C., and 125° C.) have been completed (Step S209).

Thereafter, if the measurements have been completed (Step S209/YES), the process proceeds to Step S210. If not (Step S209/NO), the process returns to Step S202 to change the set temperature of the chuck 40 and continue processing.

### [Step S210]

The calibration unit 103 compares the relationship between the infrared radiation amount and the derived temperature of the black body 30 with the relationship between the infrared radiation amount and the derived temperature of the reference device, and generates a correction table (hereinafter also referred to as the “second correction table”) (Step S210).

### [Steps S211, S212]

Steps S211 to S216 are processes for calibrating the temperature measuring device 10 by measuring the radiation amount of the black body 30 during testing or at regular intervals of semiconductor devices on the wafer 20, using the correction table created in Step S210.

First, the wafer 20 to be measured is placed on the chuck 40 (Step S211), and the electrical characteristics of the semiconductor devices on the wafer 20 are tested (Step S212).

### [Step S213]

At regular intervals, as shown in FIG. 4, the movement drive mechanism moves the black body 30 on the chuck 40 to the position of the infrared-light receiving unit 13 (Step S213).

For example, calibration using the radiation amount of the black body 30 on the chuck 40 is performed during replacement of one wafer 20 with the next wafer 20, or in the interval between tests of one semiconductor device and the next on the same wafer 20.

### [Step S214]

The infrared-light receiving unit 13 receives the infrared radiation emitted by the black body 30 and transmits it to the temperature measuring device 10. In the temperature measuring device 10, the radiation amount derivation unit 102 derives the infrared radiation amount of the black body 30 based on the infrared radiation received from the infrared sensor 16 (Step S214).

### [Step S215]

In the temperature measuring device 10, the temperature derivation unit 105 derives the temperature based on the infrared radiation amount of the black body 30 using Planck's radiation law (Step S215).

### [Step S216]

The calibration unit 103 uses the correction table generated in Step S210 and the infrared radiation amount and temperature of the black body 30 derived in Steps S211 to S215 to detect and correct time-dependent changes in the infrared sensor and changes in the infrared radiation amount of the wafer (Step S216).

### (A-2-2) Temperature Correction Processing

Next, a method for correcting the measurement value of the surface temperature of the wafer 20 by the temperature measuring device 10 will be described in detail with reference to the drawings.

### (A-2-2-1) Z-Position Temperature Correction Processing

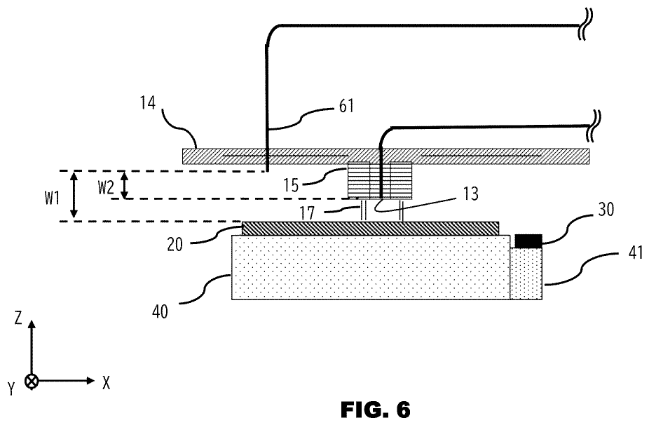

FIG. 6 is an explanatory diagram illustrating distance measurement by the distance sensor 61 according to the first embodiment.

For example, in FIG. 6, during testing, the infrared-light receiving unit 13 is positioned facing the semiconductor device on the wafer 20, and the position of the light entrance part of the infrared-light receiving unit 13 serves as the reference for measuring infrared radiation.

Assuming the position of the light entrance part (tip) of the infrared-light receiving unit 13 and the position of the tip of the distance sensor 61 are known in advance, the distance (distance in the Z-axis direction; height) between the tip of the distance sensor 61 and the light entrance part of the infrared-light receiving unit 13 is defined as “W2.”

Further, when the distance sensor 61 targets the upper surface of the wafer 20, the distance (distance in the Z-axis direction; height) between the tip of the distance sensor 61 and the upper surface of the wafer 20 is defined as “W1.”

The distance sensor 61 emits light toward the upper surface of the wafer 20 as the target, receives the reflected light, and provides the distance information to the upper surface of the wafer 20 to the Z-position temperature correction unit 111 of the temperature measuring device 10.

The Z-position temperature correction unit 111 calculates the distance between the light entrance part (tip) of the infrared-light receiving unit 13 and the upper surface of the wafer 20 based on the distance information from the distance sensor 61.

Here, an example of a method for deriving the distance between the light entrance part (tip) of the infrared-light receiving unit 13 and the upper surface of the wafer 20 by the Z-position temperature correction unit 111 will be described.

For example, the distance W2 between the tip of the distance sensor 61 and the light entrance part of the infrared-light receiving unit 13 (distance in the Z-axis direction; height) is predetermined. Therefore, the Z-position temperature correction unit 111 can derive the distance “W1−W2” between the light entrance part (tip) of the infrared sensor 16 and the upper surface of the wafer 20 by subtracting W2 from the distance W1 to the wafer 20 measured by the distance sensor 61.

The Z-position temperature correction unit 111 references the predefined relationship between the distance to the wafer 20 and the correction temperature, and determines the correction temperature corresponding to the distance (W1−W2) between the light entrance part (tip) of the infrared-light receiving unit 13 and the upper surface of the wafer 20.

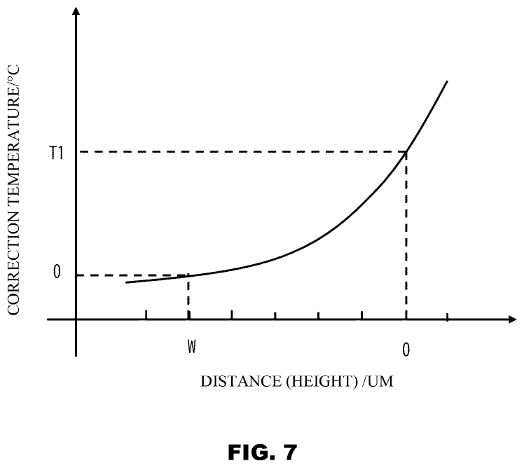

FIG. 7 is a diagram showing the relationship between the distance between the wafer 20 and the infrared-light receiving unit 13 and the correction temperature according to the first embodiment. In FIG. 7, the horizontal axis represents the length of the distance between the wafer 20 and the infrared-light receiving unit 13, and the vertical axis represents the correction temperature.

For example, as illustrated in FIG. 7, it is assumed that there is a relationship between the distance from the wafer 20 to the infrared-light receiving unit 13 and the correction temperature. As the distance until the infrared radiation emitted from the wafer 20 reaches the infrared-light receiving unit 13 increases, the incident angle of the infrared radiation on the infrared-light receiving unit 13 changes, resulting in less infrared radiation being received and a larger error in the measured temperature. The relationship shown in FIG. 7 may be obtained by collecting advance data on the distance between the actual workpiece (wafer 20) and the light entrance part, and the temperature error correction data. Using this relationship illustrated in FIG. 7, the surface temperature value of the wafer 20 can be corrected.

For example, the Z-position temperature correction unit 111 refers to the relationship shown in FIG. 7 and obtains a correction temperature corresponding to the distance (W1−W2) between the light entrance part (tip) of the infrared-light receiving unit 13 and the upper surface of the wafer 20. Then, by adding the correction temperature to the actually measured surface temperature of the wafer 20, the corrected wafer surface temperature is obtained.

### (A-2-2-2) Ambient Temperature Correction Processing

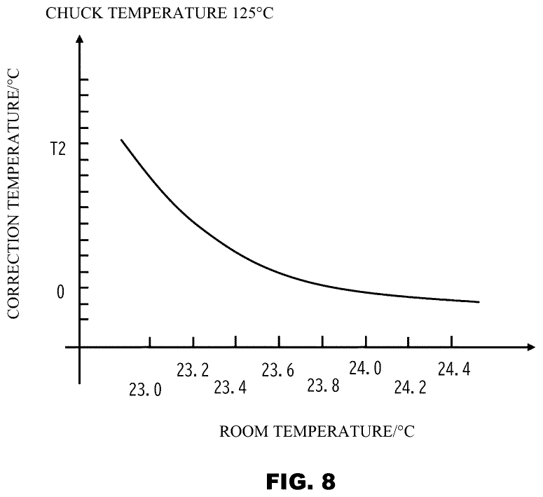

FIG. 8 is a diagram showing the relationship between ambient temperature and correction temperature according to the first embodiment. In FIG. 8, the horizontal axis represents the ambient temperature (e.g., room temperature), and the vertical axis represents the correction temperature.

For example, during the testing of electrical characteristics of the wafer 20 (semiconductor device), the temperature sensor 191 measures the ambient temperature in which the infrared-light receiving unit 13 is placed. The temperature sensor 191, which measures the ambient temperature at the time of testing, provides temperature information to the temperature measuring device 10.

In the temperature measuring device 10, the ambient temperature correction unit 112 references the relationship between ambient temperature and correction temperature shown in FIG. 8, and corrects the surface temperature of the wafer 20 in response to the temperature information (e.g., room temperature) obtained from the temperature sensor 191.

### (A-2-2-3) Fiber Temperature Correction Processing

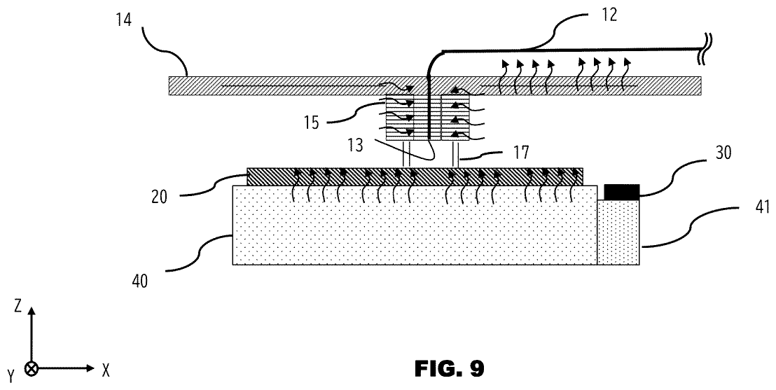

FIG. 9 is an explanatory diagram illustrating fiber temperature correction processing according to the first embodiment.

As illustrated in FIG. 9, the temperature of the optical fiber 12 itself also changes due to heat from the chuck 40 or radiant heat from the workpiece (such as the wafer 20). Since the optical fiber 12 itself also emits infrared radiation, the temperature of the optical fiber 12 itself changes, which alters the amount of infrared radiation emitted by the optical fiber 12 itself, resulting in an error in the surface temperature value of the wafer 20 measured by the temperature measuring device 10.

Therefore, the fiber temperature correction unit 113 references the relationship between the temperature of the optical fiber 12 and the correction temperature corresponding to the increase in infrared radiation emitted by the optical fiber 12, and corrects the surface temperature value of the wafer 20.

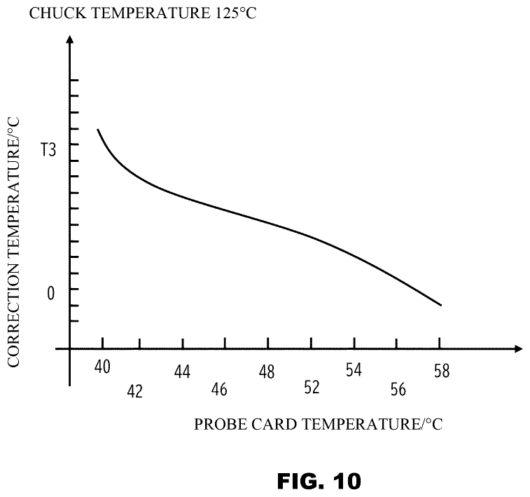

FIG. 10 is a diagram showing the relationship between the temperature of the optical fiber 12 and the correction temperature corresponding to the increase in infrared radiation from the optical fiber 12 according to the first embodiment.

For example, the relationship illustrated in FIG. 10 is obtained by varying the temperature of the optical fiber 12 and measuring the increase in infrared radiation emitted from the optical fiber 12. Then, based on the increase in infrared radiation with respect to the temperature change of the optical fiber 12, the temperature correction amount corresponding to the temperature change is derived and treated as error data affecting the actual temperature measurement of the workpiece.

Here, to measure the temperature of the optical fiber 12 itself, a temperature sensor 191 such as a thermocouple is provided at the tip of the optical fiber 12 (e.g., the infrared-light receiving unit 13).

In the temperature measuring device 10, the fiber temperature correction unit 113 references the relationship between the temperature of the optical fiber 12 and the correction temperature illustrated in FIG. 10, and corrects the surface temperature of the wafer 20 in response to the temperature information acquired from the temperature sensor 191.

### (A-2-2-4) Ferrule Temperature Correction Processing

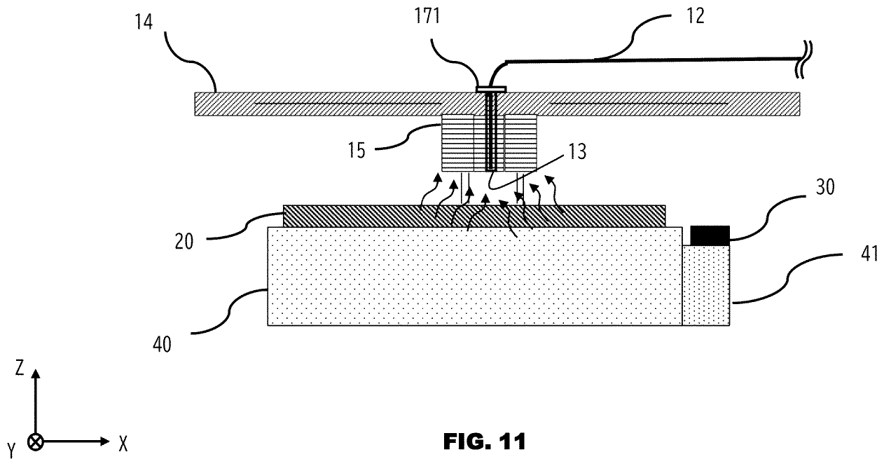

FIG. 11 is an explanatory diagram illustrating ferrule temperature correction processing according to the first embodiment.

As illustrated in FIG. 11, the probe card 14 has a through-hole through which the optical fiber 12 is inserted, and the infrared-light receiving unit 13 detects the infrared radiation emitted from the wafer 20. To facilitate replacement of the optical fiber 12, a ferrule 171, which is a flanged tubular member, is inserted into the through-hole, and then the optical fiber 12 is inserted into the tube of the ferrule 171.

The ferrule 171 inserted into the through-hole of the probe card 14 also undergoes temperature changes due to heat from the chuck 40 or radiant heat from the workpiece (such as the wafer 20). When the temperature of the ferrule 171 itself changes, the optical fiber 12 inserted through it also undergoes temperature changes, resulting in errors in the surface temperature value of the wafer 20 measured by the temperature measuring device 10.

Therefore, the ferrule temperature correction unit 114 references the relationship between the temperature of the ferrule 171 and the correction temperature corresponding to the increase in infrared radiation emitted from the optical fiber 12, and corrects the surface temperature value of the wafer 20.

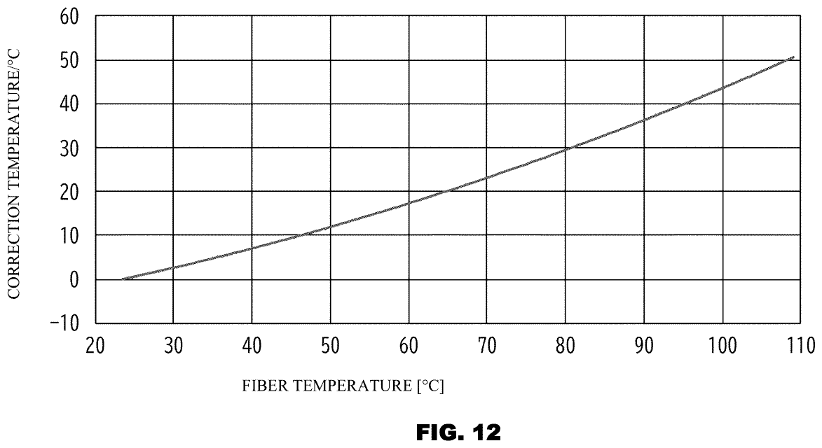

FIG. 12 is a diagram showing the relationship between the temperature of the ferrule 171 and the correction temperature corresponding to the increase in infrared radiation from the ferrule 171 according to the first embodiment.

For example, the relationship illustrated in FIG. 12 is obtained by varying the temperature of the ferrule 171 and measuring the increase in infrared radiation emitted from the ferrule 171. Then, based on the increase in infrared radiation with respect to the temperature change of the ferrule 171, the temperature correction amount corresponding to the temperature change is derived and treated as error data affecting the actual temperature measurement of the workpiece.

Here, to measure the temperature of the ferrule 171 itself, a temperature sensor 191 such as a thermocouple is provided at the tip of the ferrule 171.

In the temperature measuring device 10, the ferrule temperature correction unit 114 references the relationship between the temperature of the ferrule 171 and the correction temperature illustrated in FIG. 12, and corrects the surface temperature of the wafer 20 in response to the temperature information acquired from the temperature sensor 191.

### (A-2-2-5) Arrangement of Temperature Sensor 191

The arrangement of the temperature sensor 191 provided on the optical fiber 12 inserted into the ferrule 171 will be described with reference to the drawings.

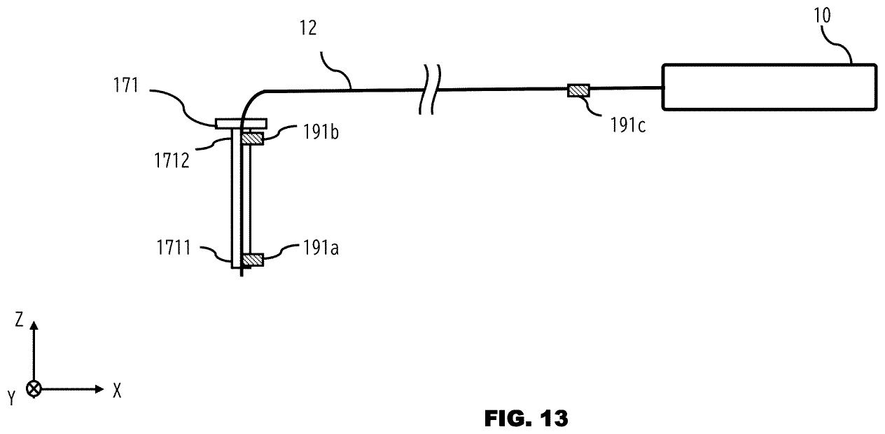

FIG. 13 is an explanatory diagram illustrating the arrangement of the temperature sensor 191 provided on the optical fiber 12 and the ferrule 171 according to the first embodiment.

When performing the ambient temperature correction processing, fiber temperature correction processing, and ferrule temperature correction processing described above, as illustrated in FIG. 13, a temperature sensor 191a is disposed on the lower end (other end) 1711 side of the ferrule 171, and a temperature sensor 191b is disposed on the upper end (one end) 1712 side of the ferrule 171. For example, the diameter of the ferrule 171 is made larger than that of the optical fiber 12, and the temperature sensors 191 are affixed to the inner wall of the ferrule 171 with an adhesive or the like. By disposing the temperature sensors 191 in such positions, it becomes possible to measure the temperature at positions where heat is easily transferred from the chuck 40 or wafer 20.

In addition, as illustrated in FIG. 13, to measure the ambient temperature, a temperature sensor 191c is disposed at a location on the optical fiber 12 that is distant from the prober 50.

### (A-3) Example

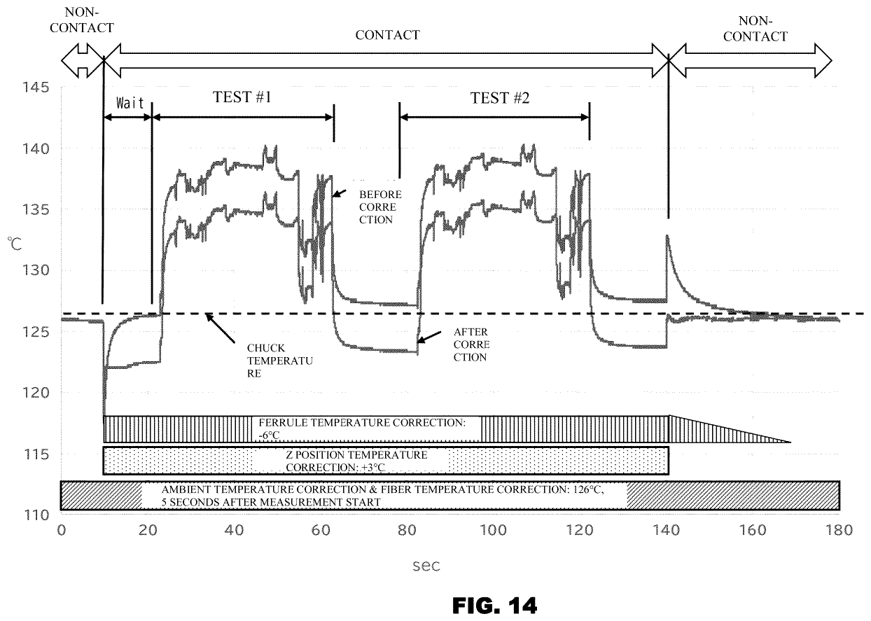

FIG. 14 is a diagram showing the surface temperature of the wafer 20 before and after correction by the temperature measuring device 10 according to the first embodiment.

The example in FIG. 14 illustrates a case in which Z-position temperature correction processing, ambient temperature correction processing, fiber temperature correction processing, and ferrule temperature correction processing were all performed.

Under the measurement conditions, the probe 17 was electrically in contact with the electrode terminal of the semiconductor device and the surface temperature of the wafer 20 (semiconductor device) was measured while electrical characteristics of the semiconductor device were being tested. In FIG. 14, the “contact” period indicates the time when the probe 17 is in contact with the electrode terminal, and the “non-contact” period indicates the time when the probe 17 is released from the electrode terminal.

The temperature of the chuck 40 was set to 126° C., and the infrared-light receiving unit 13 received the infrared radiation emitted from the wafer 20 (semiconductor device). The temperature measuring device 10 measured the surface temperature based on the amount of infrared radiation.

Furthermore, the temperature measuring device 10 performed Z-position temperature correction processing, ambient temperature correction processing, fiber temperature correction processing, and ferrule temperature correction processing.

Here, in accordance with the above-described correction methods, the temperature correction value by the Z-position temperature correction processing was set to “+3° C.,” and the temperature correction value by the ferrule temperature correction processing was set to “−6° C.” In the ambient temperature correction processing and the fiber temperature correction processing, the temperature 5 seconds after the start of measurement was set to 126° C., and the temperature correction value obtained by the above methods was used.

As shown in FIG. 14, during the “contact” period, when the temperature measuring device 10 consecutively measured the surface temperature of the wafer 20 twice, the corrected temperature was lower than the uncorrected temperature and closer to the actual temperature, thereby enabling more accurate measurement of the surface temperature of the wafer 20.

### (A-4) Effects of First Embodiment

As described above, according to the first embodiment, when the surface temperature of a wafer having multiple devices under test is measured in a non-contact manner using the infrared-light receiving unit 13 at the tip of the optical fiber 12 and the infrared sensor 16, factors that may cause measurement errors can be corrected, resulting in accurate surface temperature measurement.

### (B) Other Embodiments

Although various modifications have been mentioned in the above-described first embodiment, the present disclosure may also be applied to the following modified embodiments.

(B-1) A case where all four correction methods are performed is exemplified in the first embodiment described above, but the same effect as the first embodiment can also be obtained by performing only one of the four correction methods.

Alternatively, the same effect as the first embodiment can be obtained by combining two or three of the four correction methods.

(B-2) Although correction can be made as needed on the basis of correction values based on calibration data using a calibration black body furnace during shipment or regular calibration of the inspection apparatus, the transmittance may change due to fitting conditions or deterioration of the optical path (fiber, lens barrel, lens, etc.).

In contrast, according to this embodiment, inspection and secondary calibration using a standard emitter (i.e., black body+constant temperature) under actual usage conditions are required. A heat chuck with a black body formed on a portion thereof, or a thermo chuck separately provided with a black body, may be prepared to obtain a function of performing secondary calibration in such a manner that the difference in radiation amounts in each temperature range remains below a certain threshold.

(B-3) If the temperature of the optical path itself rises, the influence of infrared radiation generated from the optical path itself may be received. Furthermore, if the temperature at the tip of the fiber changes due to radiant heat from the workpiece, the amount of infrared radiation emitted from the fiber increases, and a temperature higher than the actual workpiece temperature may be displayed. According to this embodiment, it is possible to provide a function of making correction as needed so as to adjust temperature obtained by subtracting the influence of the fiber's temperature from the current measurement temperature, to become positive based on previously obtained data on the fiber temperature and the increase in infrared radiation.

(B-4) For wafers having the most average finish among the devices under test, or wafers used initially or for correction purposes, the error between the chuck temperature and the measured chuck surface temperature when heat is applied using a thermo chuck is measured. This makes it possible to correct measurement errors that vary depending on the design of the actual workpiece.

(B-5) A function is provided of collecting correction data for temperature errors caused by the distance between the actual workpiece and the fiber in advance, monitoring this distance information in real time, and adjusting the correction amount based on the acquired distance information. The required distance information for this correction may be obtained from a Z-axis positioning system, or a height sensor may be provided around the temperature sensor.

### REFERENCE SIGNS LIST

1, 1A: inspection apparatus
10: temperature measurement control system
11: connection wiring
12: optical fiber
13: infrared-light receiving unit
19: test head
14: probe card
15: probe assembly
16: infrared sensor
17: probe
171: ferrule (flanged tubular member)
1711: other end of ferrule
1712: one end of ferrule
18: electrical connection unit
20: wafer
30: black body
40: chuck
41: black body mounting portion
42: peripheral portion
50: prober
51: θ-axis stage
52: Z-axis stage
53: Y-axis stage
54: X-axis stage
61: distance sensor
62: optical fiber
100: measured temperature calibration unit
101: temperature acquisition unit
102: radiation amount derivation unit
103: calibration unit
104: storage unit
104a: reference table
105: temperature derivation unit
120: temperature display unit
191 (191a-191c): temperature sensor

1. An inspection apparatus which brings an electrical contactor into contact with an electrode terminal of a device under test formed on a wafer, electrically connects a tester and the device under test via the electrical contactor, and tests the device under test, the inspection apparatus comprising:
a wafer support portion configured to support the wafer;
an infrared-light receiving unit configured to receive infrared radiation emitted from the wafer, at least with the wafer as a measurement target; and
a temperature measurement control unit configured to control temperature measurement of the measurement target based on an infrared radiation amount of the infrared radiation received by the infrared-light receiving unit,
wherein the temperature measurement control unit includes a temperature correction unit configured to correct the measurement temperature based on the infrared radiation amount of the wafer.

2. The inspection apparatus according to claim 1,
wherein the temperature correction unit is configured to correct the measurement temperature in response to a temperature change in an infrared optical path from the infrared-light receiving unit to the temperature measurement control unit.

3. The inspection apparatus according to claim 2, further comprising electrical connection means disposed to face the wafer and including a plurality of the electrical contactors that make electrical contact with the electrode terminals of the device under test on the wafer,
wherein the temperature correction unit is configured to correct the measurement temperature in response to a temperature change in the electrical connection means and the infrared-light receiving unit by the wafer support portion having a temperature adjustment section.

4. The inspection apparatus according to claim 2,
wherein a tubular member is inserted into a through-hole formed in the electrical connection means,
the infrared-light receiving unit is inserted into the tube of the tubular member inserted into the through-hole, and receives infrared radiation emitted from the wafer, and
the temperature correction unit is configured to correct the measurement temperature in response to a temperature change in the electrical connection means and the infrared-light receiving unit by the wafer support portion having a temperature adjustment section.

5. The inspection apparatus according to claim 3, further comprising a distance measurement unit configured to measure a distance between the wafer supported by the wafer support portion and the infrared-light receiving unit,
wherein the temperature correction unit is configured to correct the measurement temperature in response to the distance between the wafer and the infrared-light receiving unit by referencing a predefined relationship between distance and correction temperature with respect to infrared radiation amount.

6. The inspection apparatus according to claim 3,
wherein the temperature correction unit is configured to correct the measurement temperature according to the ambient temperature where an infrared sensor associated with the infrared-light receiving unit is placed.
